(19) United States
(12) Patent Application Publication
(10) Pub. No.: US 2018/0233688 A1
(43) Pub. Date: Aug. 16, 2018

(54) Light-Emitting Diode and Manufacturing Method Thereof, Light-Emitting Device

(71) Applicant: BOE Technology Group Co., Ltd., Beijing (CN)

(72) Inventors: Zhuo Chen, Beijing (CN); Yanzhao Li, Beijing (CN)

(73) Assignee: BOE Technology Group Co., Ltd., Beijing (CN)

(21) Appl. No.: 15/570,000

(22) PCT Filed: Apr. 13, 2017
(86) PCT No.: PCT/CN2017/080377

§ 371 Date: Oct. 27, 2017

(30) Foreign Application Priority Data
Jun. 6, 2016 (CN) 201610395285.2

(51) Int. Cl. H01L 51/50; H01L 51/52; H01L 51/56; H01L 51/00

(52) U.S. Cl. CPC H01L 51/5032; H01L 51/0081; H01L 51/5056; H01L 51/5072; H01L 51/5088; H01L 51/5092; H01L 51/5096; H01L 51/5206; H01L 51/5221; H01L 51/56; H01L 51/0007; H01L 51/0026; H01L 51/001; H01L 2251/308; H01L 2251/301; H01L 51/004; H01L 2251/552; H01L 51/0043; H01L 51/0037; H01L 51/0035; H01L 51/0077; H01L 51/0059; H01L 51/006; H01L 51/0058; H01L 51/007; H01L 2051/0063; H01L 51/502

(57) ABSTRACT

A light-emitting diode (LED), a manufacturing method thereof and a light-emitting device are disclosed. The LED includes a cathode, an anode and a functional layer located between the cathode and the anode. The functional layer includes a light-emitting layer and at least one of a hole transporting layer and an electron transporting layer. At least one of the hole transporting layer and the electron transporting layer includes a material having perovskite structure expressed by a general formula of ABX₃, wherein A is RNH₃ or Cs, R is CₙH₂ₙ₊₁, n≥1; X is at least one of Cl, Br and I; B is at least one of Plumbum (Pb), Germanium (Ge), Bismuth (Bi), Stannum (Sn), Cuprum (Cu), Manganese (Mn) and Stibium (Sb).

### TECHNICAL FIELD

At least one embodiment of the present disclosure relates to a light-emitting diode, a manufacturing method thereof and a light-emitting device.

### BACKGROUND

Charge transporting layer (including at least one of a hole transporting layer and an electron transporting layer), as a very important component in organic light-emitting diode (OLED) devices and quantum dot light-emitting diode (QD-LED) devices, plays a role of injecting holes/electrons into a light-emitting layer and balancing the injection of the holes/electrons. Apart from high occupied molecular orbital (HOMO) and lowest unoccupied molecular orbital (LUMO) that need to be matched with anode work function and cathode work function, a carrier migration rate of holes or electrons is also a key parameter of hole transporting materials or electron transporting materials. The larger the carrier migration rate is, the lower the driving voltage required by the devices will be. The hole migration ratio of commonly used hole transporting materials may be ranged from 10⁻⁵ cm²/V·s to 10⁻³ cm²/V·s, while the electron migration ratio of commonly used electron transporting materials may be ranged from 10⁻⁶ cm²/V·s to 10⁻⁴ cm²/V·s.

### SUMMARY

At least one embodiment of the present disclosure relates to a light-emitting diode, a manufacturing method thereof and a light-emitting device to lower the driving voltage of the light-emitting device, reduce the power consumption of the light-emitting device and extend the lifetime of the light-emitting device.

At least one embodiment of the present disclosure provides a light-emitting diode (LED), including a cathode, an anode and a functional layer located between the cathode and the anode. The functional layer includes a light-emitting layer (LEL) and at least one of a hole transporting layer (HTL) and an electron transporting layer (ETL). At least one of the HTL and the ETL includes a material having perovskite structure, the material having perovskite structure is expressed by a general formula of ABX₃, wherein A is RNH₃ or Cs, R is CₙH₂ₙ₊₁, n≥1; X is at least one of Cl, Br and I; B is at least one of Plumbum (Pb), Germanium (Ge), Bismuth (Bi), Stannum (Sn), Cuprum (Cu), Manganese (Mn) and Stibium (Sb).

At least one embodiment of the present disclosure provides a manufacturing method of a light-emitting diode (LED), including: forming a cathode and an anode; and forming a functional layer located between the cathode and the anode. Forming a functional layer includes: forming a light-emitting layer (LEL) and at least one of a hole transporting layer (HTL) and an electron transporting layer (ETL). At least one of the HTL and the ETL includes a material having perovskite structure, the material having perovskite structure is expressed by a general formula of ABX₃, wherein A is RNH₃ or Cs, R is CₙH₂ₙ₊₁, n≥1; X is at least one of Cl, Br and I; B is at least one of Plumbum (Pb), Germanium (Ge), Bismuth (Bi), Stannum (Sn), Cuprum (Cu), Manganese (Mn) and Stibium (Sb).

At least one embodiment of the present disclosure provides a light-emitting device including the light-emitting diode provided by at least one embodiment of the present disclosure.

### BRIEF DESCRIPTION OF THE DRAWINGS

Hereafter, the embodiments of the present invention will be described in details with reference to the drawings, so as to make one person skilled in the art understand the present invention more clearly.

FIG. 1 is a schematic diagram illustrating a light-emitting diode provided by an embodiment of the present disclosure;

FIG. 2 is a schematic diagram illustrating another light-emitting diode provided by an embodiment of the present disclosure; and

FIG. 3 is a schematic diagram illustrating yet another light-emitting diode provided by an embodiment of the present disclosure.

### REFERENCE NUMERALS

1—light-emitting diode (LED); 101—anode; 102—hole injecting layer (HIL); 103—hole transporting layer (HTL); 104—light-emitting layer (LEL); 105—electron transporting layer (ETL); 106—electron injecting layer (EIL); 107—cathode; 108—electron barrier layer; 109—hole barrier layer.

### DETAILED DESCRIPTION

Hereafter, the technical solutions in the embodiments of the present disclosure will be clearly, completely described with reference to the drawings in the embodiments of the present disclosure. Obviously, the embodiments described are only a part of the embodiments, not all embodiments. Based on the embodiments in the present disclosure, all other embodiments obtained by one skilled in the art without paying inventive labor are within the protection scope of the present disclosure.

Unless otherwise defined, all the technical and scientific terms used herein have the same meanings as commonly understood by one of ordinary skill in the art to which the present invention belongs. The terms “first,” “second,” etc., which are used in the description and the claims of the present application for invention, are not intended to indicate any sequence, amount or importance, but distinguish various components. Also, the terms such as “a,” “an,” etc., are not intended to limit the amount, but indicate the existence of at least one. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

Perovskite material is an inorganic semiconductor material with a general formula of ABX₃. In recent years, organic/inorganic compound perovskite materials represented by CH₃NH₃PbI₃ have been rapidly developed in the application field of solar cell. One of the characteristics of the perovskite material is relatively larger migration rate of holes and electrons. Based on computations, the migration rate of holes in the perovskite material may reach 7.5 cm²/V·s, and the migration rate of electrons may reach 12.5 cm²/V·s (Carlito S. Ponseca, Jr et al, Journal of American Chemical Society, 2014, 138, 5189; Paolo Umari, et al, Scientific Reports, 2014, 4, 4467), both of which are much higher than that of commonly used organic hole transporting materials or electron transporting materials. Therefore the perovskite material may be one of preferable choices for hole transporting material or electron transporting material.

In the embodiments of the present disclosure, the perovskite material allows for adjustment of HOMO and LUMO by utilizing variable negative ions and positive ions in the perovskite material, so as to match the HOMO and the LUMO with the work functions of the cathode and the anode. In the embodiments of the present disclosure, a film of material having perovskite structure may be prepared by spin-coating through solution method or evaporation method, so as to be compatible with the manufacturing process of light-emitting diodes (LEDs). In the embodiments of the present disclosure, the LED may include organic light-emitting diode (OLED) and quantum dot light-emitting diode (QD-LED).

Hereinafter description will be given with reference to several embodiments, by way of example.

### The First Embodiment

The present embodiment provides a light-emitting diode (LED), including a cathode, an anode and a functional layer formed between the cathode and the anode. Forming the functional layer includes forming a light-emitting layer (IEL) and forming at least one of a hole transporting layer (HTL) and an electron transporting layer (ETL). At least one of the HTL and the ETL includes a material having perovskite structure which can be expressed by a general formula of ABX₃, wherein A is RNH₃ or Cs, R is CₙH₂ₙ₊₁, n≥1; X is at least one of Cl, Br and I; B is at least one of Plumbum (Pb), Germanium (Ge), Bismuth (Bi), Stannum (Sn), Cuprum (Cu), Manganese (Mn) and Stibium (Sb).

The present embodiment uses a material having perovskite structure as the material of the charge transporting layer (hereinafter also referred to as “charge transporting material” in the LED (e.g., OLED or QD-LED). In view of the relatively larger carrier migration rate of the material having perovskite structure, the driving voltage of the light-emitting device will be significantly lowered, the power consumption of the light-emitting device will be reduced, and the lifetime of the light-emitting device will be extended.

For example, in case that A is RNH₃, the LED provided by the present embodiment may include inorganic/organic compound material, for example, lead halide methylamine (e.g., CH₃NH₃PbI₃), lead halide ethylamine and the like. The element “lead” contained in lead halide methylamine or lead halide ethylamine may be replaced by at least one of Plumbum (Pb), Germanium (Ge), Bismuth (Bi), Stannum (Sn), Cuprum (Cu), Manganese (Mn) and Stibium (Sb).

For example, in case that A is Cs, the LED provided by the present embodiment is made from an inorganic material, for example, the inorganic material includes CsPbI₃, CsPbIₓBr₃₋ₓ, CsGeI₃, CsCuI₃, CsMnI₃ and the like, wherein 0<x<3.

For example, in the above-mentioned general formula, X is any one of Cl, Br and I. In other examples, X is any two of Cl, Br and I, and a molar ratio of the two elements may be a random one. For example, the molar ratio of the two elements is (1-2):1. For example, X is any two of Cl, Br and I, and the molar ratio of the two elements is 1:1. In other examples, X is Cl, Br and I, and the molar ratio of Cl, Br and I is a random value. For example, the molar ratio of Cl, Br and I may be (1-2):1:(1-2). Further, for example, the molar ratio of Cl, Br and I may be 1:1:1. By adjusting the negative ions, materials having perovskite structure may be obtained with different charge migration rates.

The material having perovskite structure allows for flexible adjustment in that: the carrier migration rate and the energy level of HOMO/LUMO in the material having perovskite structure may be adjusted by methods like adjusting organic ammonium ions, utilizing inorganic positive ions, adjusting negative halogen ions, utilizing mixed negative ions, and the like.

The electron transporting material and the hole transporting material in a single LED may be the same. The material having perovskite structure is characterized by that: both of the hole migration rate and the electron transport rate thereof are extremely high, and that: the holes and electrons in a layer of material having perovskite structure are difficult to be recombined. Of course, the electron transporting material may be different from the hole transporting material. In some examples, the LED includes both of the ETL and the HTL which may be made from a same material for convenience of manufacture; that is, using a same material having perovskite structure. Of course, the HTL and the ETL may be made from different materials. For example, one of the HTL and the ETL may be made from a material having perovskite structure, and the other one may be made from common material; or, the HTL and the ETL may be made from different materials having perovskite structure; without particularly defined in the embodiments of the present disclosure. Of course, the LED in the present embodiment may only include one of the ETL and the HTL, without limiting the embodiments of the present disclosure thereto.

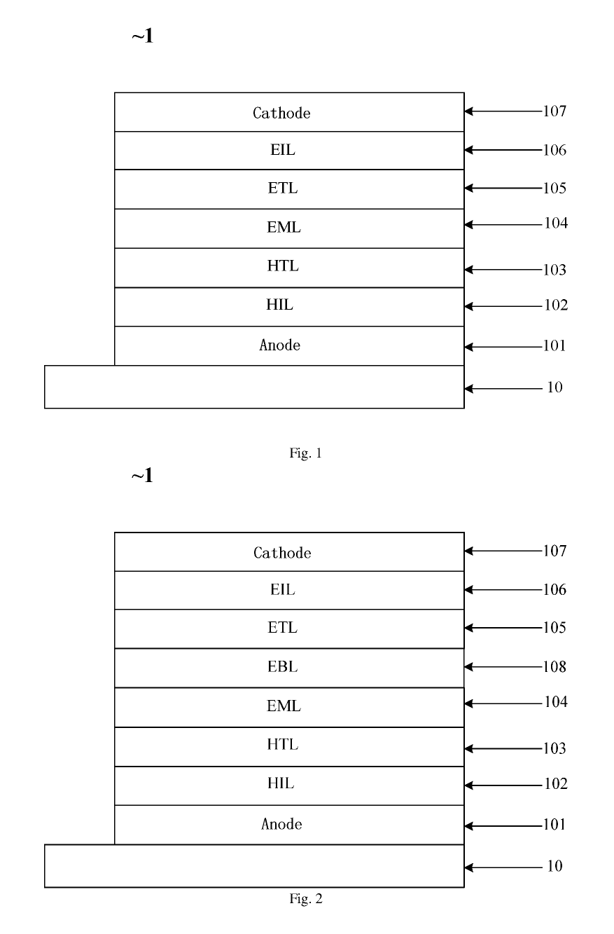

In some examples, as illustrated in FIG. 1, the LED 1 includes: a substrate 10; and an anode 101, a hole injecting layer (HIL) 120, a hole transporting layer (HTL) 103, a light-emitting layer (LML) 104, an electron transporting layer (ETL) 105, an electron injecting layer (EIL) 106 and a cathode 107 which are disposed on the substrate 10. At least one of the HTL 103 and the ETL 105 may include the above-mentioned material having perovskite structure. For example, the above-mentioned layers may be successively disposed in lamination. It should be explained that, in the LED 1 provided by another example, only one of the HIL 102 and the EIL 106 is disposed; or, neither the HIL 102 nor the EIL 106 is disposed. Of course, it may also be possible that only one of the HTL 103 and the ETL 105 is disposed. In addition, the above-mentioned laminated structure is merely described by way of example, and some of these layers may be omitted from the LED provided by the embodiments of the present disclosure, or some other layers may be added, without particularly defined in the embodiments of the present disclosure.

For example, the substrate 10 may be a glass substrate; the anode 101 may be made from transparent conductive material, for example, transparent conductive metallic oxide. Furthermore, for example, the anode 101 may be made from Indium Tin Oxide (ITO); the HIL 102 may be made from a material including poly(3,4-ethylenedioxythiophene)/polystyrene sulfonate (PEDOT: PSS); the LEL 104 may be an organic LEL or a quantum dot LEL; the EIL 106 may be made from a material including LiF, nano-zinc oxide and the like; and the cathode 107 may be made from a material including Al, Ag and the like.

For example, depending on the type of the organic light-emitting material as used, the LEL may emit red light, green light, blue light, yellow light, white light, and the like. The organic light-emitting material includes any one of fluorescence material and phosphorescent material.

The quantum dot is also referred to as nano-crystalline. For example, it may be a nano-particle consisted by II-VI group element or III-V group element. A grain size of the quantum dot usually is ranged from 1 nm to 10 nm; due to quantum confinement subjected by electrons and holes, the continuous energy band structure will be turned into a discrete energy level structure, which possesses molecular properties and allows emitting fluorescence upon stimulated.

It should be explained that, the materials of the anode 101, the HIL 102, the LEL 104, the EIL 106 and the cathode 107 are not limited to those listed herein, but may be other ones without particularly defined in the present embodiment.

In a LED using a thin-film material having perovskite structure as the HTL and/or the ETL, the electron injection may be more than the hole injection. Under such circumstance, the electron injection may be delayed by using an electron barrier layer (or an electron buffer layer) to balance the hole injection and the electron injection.

Similarly, in a LED using a thin-film material having perovskite structure as the HTL and/or the ETL, it's also possible that the hole injection is more than the electron injection. Under such circumstance, the hole injection may be delayed by using a hole barrier layer (or a hole buffer layer) to balance the hole injection and the electron injection.

In some examples, as illustrated in FIG. 2, for the purpose of balancing the rate of injecting holes into the LEL and the rate of injecting electrons into the LEL, an electron barrier layer 108 is disposed between the LEL 104 and the ETL 105. The electron barrier layer 108 is configured to slower the rate of injecting electrons into the LEL 104. For example, the electron barrier layer 108 may be made from an organic, electron transporting material which has an electron transport rate smaller (slower) than an electron transport rate of an ETL 105 made from a material having perovskite structure. For example, the electron barrier layer may be made from a material including at least one of polymethyl methacrylate (PMMA) and polyvinyl carbazole (PVK), or other polymers with high LUMO value, without particularly defined in the present embodiment.

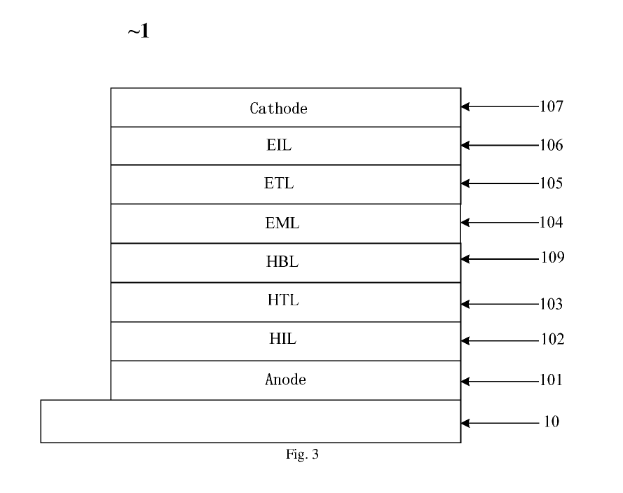

In some examples, as illustrated in FIG. 3, for the purpose of balancing the rate of injecting holes into the LEL and the rate of injecting electrons into the LEL, a hole barrier layer 109 is disposed between the LEL 104 and the HTL 103. The hole barrier layer 109 is configured to slower the rate of injecting holes into the LEL 104. For example, the hole barrier layer 109 may be made from an organic, hole transporting material which has a hole transport rate smaller (slower) than a hole transport rate of an HTL 103 made from a material having perovskite material. For example, the hole barrier layer may be made from a material including at least one of N,N′-bis(3-methyl-phenyl)-N,N′-diphenyl-1,1′-diphenyl-4,4′-diamine (TPD); 4,4′,4″-tris(carbazol-9-yl)-triphenylamine (TcTa); 2-(4-diphenyl)-5-(4-t-butylphenyl)-1,3,4-oxadiazole (PBD); N,N′-bis(1-naphthyl)-N,N′-diphenyl-1,1′-diphenyl-4,4′-diamine (NPB); 4,4′-cyclohexylidenebis[N,N-bis(4-methylphenyl)aniline] (TAPC); N,N,N′,N′-tetrafluorenyl benzidine (FFD); triphenylamine tetramer (TPTE); and TFB, wherein TFB is [9,9′-dioctylfluorene-copoly-N-(4-butoxybenzyl)-diphenylamine)]m, wherein m>100.

### The Second Embodiment

The present embodiment provides a manufacturing method of a light-emitting diode (LED), including: forming a cathode and an anode; and forming a functional layer located between the cathode and the anode. Forming the functional layer includes: forming at least one of a hole transporting layer (HTL) and an electron transporting layer (ETL), and forming a light-emitting layer (LEL). At least one of the HTL and the ETL includes a material having perovskite structure which may be expressed by a general formula of ABX₃, wherein A is RNH₃ or Cs, R is CₙH₂ₙ₊₁, n≥1; X is at least one of Cl, Br and I; B is at least one of Plumbum (Pb), Germanium (Ge), Bismuth (Bi), Stannum (Sn), Cuprum (Cu), Manganese (Mn) and Stibium (Sb). For example, any of the LEDs provided by the first embodiment may be manufactured by the method provided in the present embodiment.

For example, the LED may be manufactured by a solution process.

For example, forming the material having perovskite structure may include steps as below.

Preparing a solution of metal halide, the metal halide contains a metallic element which is at least one of Plumbum (Pb), Germanium (Ge), Bismuth (Bi), Stannum (Sn), Cuprum (Cu), Manganese (Mn) and Stibium (Sb), and contains a halogen element which is at least one of Cl, Br and I.

Coating the solution of metal halide onto a substrate and annealing the substrate having been coated with the solution of metal halide, so as to obtain a thin film of metal halide.

Immersing the substrate having been formed with the thin film of metal halide into a solution of cesium halide or halogenated alkylamine to obtain a material having perovskite structure (a thin film of material having perovskite structure) which may be used for the HTL or the ETL.

For example, the solution of cesium halide or halogenated alkylamine may adopt alcoholic solutions as the solvent, e.g., the alcoholic solution may include isopropyl alcohol, without particularly defined in the present embodiment.

For example, prior to immersing the substrate having been formed with the thin film of metal halide into the solution of cesium halide or halogenated alkylamine, immersing the thin film of metal halide into an alcoholic solution for a certain time period, e.g., 1-5 min. The alcoholic solution may include, for example, isopropyl alcohol, without limiting embodiments of the present disclosure thereto. This facilitates removing the metal halide having not been formed into the film.

For example, the solution of metal halide has a concentration of 0.1 mol/L-2 mol/L.

For example, the solution of metal halide adopts at least one of N,N′-dimethylformamide, dimethyl sulfoxide and γ-butyrolactone as the solvent.

For example, upon obtaining the thin film of material having perovskite structure, further processes such as cleaning and drying by baking may be performed for purpose of proceeding with subsequent operations. For example, the thin film of material having perovskite structure may be cleaned in the isopropyl alcohol, and may be heated for 20-40 min on a heating stage at a temperature of 140° C.-160° C. for drying. This facilitates removing the cesium halide or the halogenated alkylamine which has not been reacted.

In a first example, manufacturing the LED by solution process may include steps as below.

(I), Cleaning a Glass Substrate Containing an ITO Transparent Electrode (i.e., an Anode).

For example, this step may be achieved by: continuously applying ultrasound to the glass substrate for 15 min by using deionized water and isopropyl alcohol, respectively; quickly drying the glass substrate by using a nitrogen gas gun; baking the glass substrate on a heating stage at 150° C. for 5 min; treating the glass substrate for half a hour by using UV-ozone, so as to clean the ITO surface of the glass substrate and improve ITO work function.

(II), Preparing a Hole Injection Layer (HIL)

For example, this step may be achieved by: spin-coating PEDOT: PSS (e.g., spin-coating for 1 min) onto the glass substrate have been cleaned at a rate of 3000 RPM (revolutions per minute) in air; annealing the glass substrate in air, e.g., annealing at 130° C. for 20 min to dry the solvent having not been volatilized, and transferring the glass substrate into a glove box in which all the subsequent steps (e.g., preparation of the HPL, the LEL, the ETL, the EIL and the cathode). The glove box maintains an oxygen-free environment, e.g., a nitrogen environment or an argon atmosphere, without limiting the embodiments of the present disclosure thereto.

(III), Preparing a Hole Transporting Layer (HTL) Having Perovskite Structure

For example, the HTL having perovskite structure may be prepared by: firstly preparing a solution of lead iodide at a molar ratio of 0.1 mol/L-2 mol/L by using any one or more of N,N′-dimethylformamide, dimethyl sulfoxide and γ-butyrolactone mixed at any ratios as the solvent; pre-heating the solution of lead iodide at 150° C. to fully dissolve the lead iodide. Spin-coating the solution of lead iodide as prepared onto a thin film of PEDOT: PSS (e.g., spin-coating at a rate of 2000 RPM for 2 min) and then annealing for 30 min on a heating stage at 150° C. to obtain a thin film of lead iodide. Thereafter, immersing the thin film of lead iodide in isopropyl alcohol for 1 min and then immersing the same in a solution of methyl-ammonium iodide with isopropyl alcohol as the solvent, at a molar ratio of 1 mg/mL-60 mg/mL for 30 min, to obtain a thin film of CH₃NH₃PbI₃. Immersing the thin film of CH₃NH₃PbI₃ having perovskite structure in isopropyl alcohol for cleaning for 10 min, and then heating for 30 min on the heating state at 150° C.

IV. Preparing a Light-Emitting Layer (LEL)

For example, the LEL may be prepared by: spin-coating a PVK solution with toluene as the solvent (at a concentration of 20 mg/mL, and spin-coating for 45 sec) at a rate of 2000 RPM onto the thin film having perovskite structure, and then annealing for 30 min in the glove box at 180° C.

V. Preparing an Electron Transporting Layer (ETL) Having Perovskite Structure

For example, the ETL having perovskite structure may be prepared by a step similar with step III.

VI. Forming an Electron Injection Layer (EIL) and a Cathode by Evaporation Process

For example, the cathode may be formed by: placing the device having been subjected to spin-coating into a vacuum evaporation chamber to form a LiF (EIL) with a thickness of 1 nm and an Al cathode with a thickness of 100 nm, so as to obtain the OLED device of the present example.

It should be explained that, the solution of lead iodide in the first example may be replaced by a mixture of a solution of lead chloride, a solution of lead bromide and a solution of lead iodide, so as to obtain a material having perovskite structure which provides a different charge transport rate.

In a second example, on the basis of the first example, an electron barrier layer is further formed between the LEL and the ETL. The electron barrier layer may be a polymethyl methacrylate (PMMA) layer. For example, the PMMA electron barrier layer may be prepared by: spin-coating a solution of polymethyl methacrylate (PMMA), with acetone as the solvent, onto the LEL; and drying the acetone solvent by baking to obtain the PMMA electron barrier layer. The thickness of the PMMA electron barrier layer may be ranged from 5 nm to 8 nm.

In a third example, the LED may be manufactured by steps as below.

I. cleaning a glass substrate containing an ITO transparent electrode (i.e., an anode) in a manner similar with the first example.

II. preparing a hole injection layer (HIL) in a manner similar with the first example.

III. preparing a hole transporting layer (HTL) having perovskite structure by: firstly preparing a solution of lead iodide, at a molar ratio of 0.1 mol/L-2 mol/L, with any one or more of N,N′-dimethylformamide, dimethyl sulfoxide and γ-butyrolactone mixed at any ratios as the solvent; pre-heating the solution of lead iodide at 150° C. to fully dissolve the lead iodide. Spin-coating the solution of lead iodide as prepared onto a thin film of PEDOT: PSS (e.g., spin-coating at a rate of 2000 RPM for 2 min) and then annealing for 30 min on a heating stage at 150° C. to obtain a thin film of lead iodide. Thereafter, immersing the thin film of lead iodide in isopropyl alcohol for 1 min and then immersing the same in a solution of ethylamine iodide with isopropyl alcohol as the solvent, at a molar ratio of 1 mg/mL-60 mg/mL for 30 min, to obtain a thin film of CH₃CH₂NH₃PbI₃. Immersing the thin film of CH₃CH₂NH₃PbI₃ having perovskite structure in isopropyl alcohol for cleaning for 10 min, and then heating for 30 min on the heating state at 150° C.

IV. preparing a light-emitting layer (LEL) by: spin-coating a solution of CdSe/ZnS quantum dot (e.g., the CdSe/ZnS quantum dot has a core-shell structure with CdSe as the core and ZnS as the shell), with toluene as the solvent, onto a thin film of HTL having perovskite structure at a rate of 3000 RPM (e.g., a concentration of 30 mg/mL, and spin-coating for 45 sec); and annealing for 30 min in the glove box at 180° C.

V. preparing an electron barrier layer by: spin-coating a solution of PVK, with chlorobenzene as the solvent, onto the LEL; and drying the chlorobenzene solvent by baking to obtain a PVK film. The thickness of the PVK film may be ranged from 5 nm to 8 nm.

VI. preparing an electron transporting layer (ETL) in a manner similar with step III in the present example.

VII. forming a cathode by evaporation process including: placing the device having been subjected to spin-coating into a vacuum evaporation chamber to form Al cathode with a thickness of 100 nm, for example, so as to obtain the LED device of the present example.

The third example has been described with reference to the case where the electron barrier layer is made from PVK. However, the electron barrier layer may also be made from other materials mentioned in the present disclosure, without particularly defined herein.

With the arrangement of the electron barrier layer, the electron injection may be delayed. In view of the electron barrier layer, the electron transport rate is slowed to a certain extent, but the utilization of holes is improved to the largest extent and meanwhile the injection of holes and electrons can be balanced. As compared to the case where no electron barrier layer is disposed, the luminous efficiency is increased, the driving voltage is decreased, the power consumption is reduced and the lifetime is extended.

In a fourth example, the LED may be manufactured by steps as below.

I. cleaning a glass substrate containing an ITO transparent electrode (i.e., an anode) in a manner similar with the first example.

II. preparing a hole injection layer (HIL) in a manner similar with the first example.

III. preparing a hole transporting layer (HTL) having perovskite structure by: firstly preparing a solution of lead iodide, at a molar ratio of 0.1 mol/L-2 mol/L, with any one or more of N,N′-dimethylformamide, dimethyl sulfoxide and γ-butyrolactone mixed at any ratios as the solvent; pre-heating at 150° C. to fully dissolve the lead iodide. Spin-coating the solution of lead iodide as prepared onto a thin film of PEDOT: PSS (e.g., spin-coating at a rate of 2000 RPM for 2 min) and then annealing for 30 min on a heating stage at 150° C. to obtain a thin film of lead iodide. Thereafter, immersing the thin film of lead iodide in isopropyl alcohol for 1 min and then immersing the same in a solution of cesium iodide with propyl alcohol as the solvent, at a molar ratio of 1 mg/mL-60 mg/mL for 30 min to obtain a thin film of CsPbI₃ having perovskite structure. Immersing the thin film of CsPbI₃ having perovskite structure in isopropyl alcohol for cleaning for 10 min, and then heating for 30 min on the heating state at 150° C.

IV. preparing a light-emitting layer (LEL) by: spin-coating a solution of CdSe/ZnS quantum dots (e.g., the CdSe/ZnS quantum dot has a core-shell structure with CdSe as the core and ZnS as the shell) with toluene as the solvent (e.g., at a concentration of 30 mg/mL, spic-coating for 45 sec) onto the thin film of CsPbI₃ having perovskite structure, at a rate of 3000 RPM; and then annealing for 30 min in a glove box at 180° C.

V. preparing an electron transporting layer (ETL) by: spin-coating a solution of ZnO nano-particles with ethanol as the solvent (e.g., at a concentration of 30 mg/mL, a rate of 1500 RPM, for a time of 45 sec) onto the quantum dot LEL to obtain a ZnO ETL, the ZnO nano-particle has a grain size not larger than 5 nm.

VI. forming a cathode by evaporation process including: placing the device having been subjected to spin-coating into a vacuum evaporation chamber to form Al cathode with a thickness of 100 nm, for example, so as to obtain the OLED device of the present example.

In a fifth example, on the basis of the fourth example, a hole barrier layer is further formed between the LEL and the HTL. The hole barrier layer may be made from a material such as N,N′-bis(3-methylphenyl)-N,N′-diphenyl-1,1′-diphenyl-4,4′-diamine (TPD).

The fifth example has been described with reference to the case where the hole barrier layer is made from PTD. However, the hole barrier layer may also be made from other materials mentioned in the present disclosure, without particularly defined herein.

With the arrangement of the hole barrier layer, the hole injection may be delayed. In view of hole barrier layer, the hole transport rate is slowed to a certain extent, but the utilization of electrons is improved to the largest extent and meanwhile the injection of holes and electrons can be balanced. As compared to the case where no hole barrier layer is disposed, the luminous efficiency is increased, the driving voltage is decreased, the power consumption is reduced and the lifetime is extended. In the fifth example, no material having perovskite structure is adopted to form the ETL. Given that the material of ETL in the fifth example is replaced by a material having perovskite structure, then the luminous efficiency will be further increased, the driving voltage will be further decreased, the power consumption will be further reduced and the lifetime will be further extended.

It should be noted that, in the present embodiment, it's also possible that the HTL is made from commonly used materials (materials having no perovskite structure), while the ETL is made from materials having perovskite structure as described in the present embodiment.

By forming a material having perovskite structure that may be used in HTL and/or ETL through the methods of the present embodiment, in view of the relatively high hole/electron transport rate in the material having perovskite structure, the driving voltage of the light-emitting device may be significantly reduced, the power consumption of the light-emitting device may be decreased and the lifetime may be extended.

### The Third Embodiment

The present embodiment is distinct from the second embodiment in that, at least one of the HTL and the ETL of the LED is prepared by evaporation process.

For example, forming at least one of HTL and ETL from a material having perovskite structure includes: forming a material having perovskite structure on a substrate by evaporation process.

For example, an evaporation source includes AXₐ and BX_{b}, wherein a and b are subscripts representing component ratios, respectively.

For example, two evaporation sources may be provided, and a same evaporation rate may be adopted. Providing more than two evaporation sources is also possible. For example, three evaporation sources may be provided, i.e., AX′ₐ, BX′_{b} and BX″_{c}, wherein X′ and X″ are any two of Cl, Br and I; a, b and c are subscripts representing component ratios, respectively. These three evaporation sources may be evaporated at different evaporation rates, for example, the evaporation rate of AX may be a sum of evaporation rates of BX₂ and BY₂. Neither the amount nor the evaporation rate of the evaporation sources will be particularly defined in the present embodiment.

Forming the material having perovskite structure by evaporation process may utilize two evaporation sources which are lead iodide and methylamine iodide, respectively. By evaporating at a same evaporation rate, the two different materials will be reacted with each other on the substrate to generate CH₃NH₃PbI₃. Of course, other materials (e.g., lead bromide and ethyl-ammonium iodide) may also be used as the evaporation source, and several evaporation sources may be co-evaporated. For example, at least two selected from lead chloride, lead bromide and lead iodide may be co-evaporated with halogenated alkyl-ammonium (e.g., methyl-ammonium iodide). The constituents in the material having perovskite structure may be controlled by controlling different evaporation rates. The resultant material may be expressed by a general formula of ABX₃, wherein A is RNH₃ or Cs, R is CₙH₂ₙ₊₁, n≥1; X is at least one of Cl, Br and I; B is at least one of Plumbum (Pb), Germanium (Ge), Bismuth (Bi), Stannum (Sn), Cuprum (Cu), Manganese (Mn) and Stibium (Sb).

In a sixth example, the LED may be manufactured by steps as below.

I. cleaning a glass substrate containing an ITO transparent electrode in a manner similar with first example.

II. preparing a hole injection layer (HIL) by: placing the ITO glass substrate having been cleaned into a vacuum evaporation chamber to form a film of NPB with a thickness of 40 nm.

III. preparing a hole transporting layer (HTL) having a perovskite structure by: simultaneously evaporating lead iodide and methyl-ammonium iodide onto the film of NPB in the vacuum evaporation chamber, so as to form a thin film of CH₃NH₃PbI₃ having perovskite structure on the film of NPB.

IV. preparing a light-emitting layer (LEL) by: evaporating a thin film of 2-(4-diphenyl)-5-(4-t-butylphenyl)-1,3,4-oxadiazole (PBD)/8-hydroxyquinoline aluminum (Alq₃) with a thickness of 60 nm onto the HTL having perovskite structure.

V. preparing an electron transporting layer (ETL) having perovskite structure in a manner similar with the step III in the present example.

VI. forming an electron injection layer (EIL) and a cathode in a manner similar with the first example.

As for the advantageous effects of the present embodiment, reference may be made to the third embodiment, without repeating herein.

### The Fourth Embodiment

The present embodiment provides a light-emitting device including the LED in any of the foregoing embodiments.

The following statements should be noted:

I. Unless otherwise defined, throughout the embodiments and the drawings of the present disclosure, similar references indicate similar meanings;

II. The accompanying drawings involve only the structure(s) in connection with the embodiment(s) of the present disclosure, and other structure(s) can be referred to common design(s);

III. For the purpose of clarity only, in accompanying drawings for illustrating the embodiment(s) of the present disclosure, the thickness and size of a layer or a structure may be enlarged. However, it should understood that, in the case in which a component or element such as a layer, film, area, substrate or the like is referred to be “on” or “under” another component or element, it may be directly on or under the another component or element or a component or element is interposed there-between; and

IV. In case of no conflict, features in one embodiment or in different embodiments can be combined.

The foregoing are merely specific embodiments of the invention, but not limitative to the protection scope of the invention. Within the technical scope disclosed by the present disclosure, any alternations or replacements which can be readily envisaged by one skilled in the art shall be within the protection scope of the present disclosure. Therefore, the protection scope of the invention shall be defined by the accompanying claims.

The present invention claims the benefits of Chinese patent application No. 201610395285.2, which was filed with the SIPO on Jun. 6, 2016 and is fully incorporated herein by reference as part of this application.

1. A light-emitting diode (LED), comprising: a cathode; an anode; and a functional layer located between the cathode and the anode,
the functional layer comprises a light-emitting layer (LEL) and at least one of a hole transporting layer (HTL) and an electron transporting layer (ETL),
at least one of the HTL and the ETL comprises a material having perovskite structure expressed by a general formula of ABX₃, wherein A is RNH₃ or Cs, R is CₙH₂ₙ₊₁, n≥1; X is at least one of Cl, Br and I; B is at least one of Plumbum (Pb), Germanium (Ge), Bismuth (Bi), Stannum (Sn), Cuprum (Cu), Manganese (Mn) and Stibium (Sb).

2. The light-emitting diode (LED) according to claim 1, wherein the HTL and the ETL are made from a same material.

3. The light-emitting diode (LED) according to claim 1, wherein the ETL is located between the cathode and the LEL; and
an electron barrier layer is disposed between the LEL and the ETL.

4. The light-emitting diode (LED) according to claim 3, wherein the electron barrier layer is made from a material including at least one of polymethyl methacrylate (PMMA) and polyvinyl carbazole (PVK).

5. The light-emitting diode (LED) according to claim 1, wherein the HTL is located between the anode and the LEL; and
a hole barrier layer is disposed between the LEL and the HTL.

6. The light-emitting diode (LED) according to claim 5, wherein the hole barrier layer is made from a material including at least one of:
N,N′-bis(3-methyl-phenyl)-N,N′-diphenyl-1,1′-diphenyl-4,4′-diamine (TPD);
4,4′,4″-tris(carbazol-9-yl)-triphenylamine (TcTa);
2-(4-diphenyl)-5-(4-t-butylphenyl)-1,3,4-oxadiazole (PBD);
polyvinyl carbazole (PVK);
N,N′-bis(1-naphthyl)-N,N′-diphenyl-1,1′-diphenyl-4,4′-diamine (NPB);
4,4′-cyclohexylidenebis[N,N-bis(4-methylphenyl)aniline] (TAPC);
N,N,N′,N′-tetrafluorenyl benzidine (FFD);
triphenylamine tetramer (TPTE); and
TFB,
wherein TFB is [9,9′-dioctylfluorene-copoly-N-(4-butoxybenzyl)-diphenylamine)]m, and wherein m>100.

7. The light-emitting diode (LED) according to claim 1, wherein the functional layer further comprises a hole injection layer (HIL) and an electron injection layer (EIL),
the anode is made from a transparent conductive material; the HIL is made from a material including poly(3,4-ethylenedioxythiophene)/polystyrene sulfonate (PEDOT: PSS); the LEL is an organic LEL or a quantum-dot LEL; the EIL is made from a material including LiF or nano-zinc oxide; and the cathode is made from a material including Al or Ag.

8. The light-emitting diode (LED) according to claim 1, comprising at least one of an organic light-emitting diode (OLED) and a quantum dot light-emitting diode (QD-LED).

9. A manufacturing method of a light-emitting diode (LED), comprising:
forming a cathode and an anode; and forming a functional layer located between the cathode and the anode,
forming a functional layer comprises: forming at least one of a hole transporting layer (HTL) and an electron transporting layer (ETL); and forming a light-emitting layer (LEL),
at least one of the HTL and the ETL comprises a material having perovskite structure expressed by a general formula of ABX₃, wherein A is RNH₃ or Cs, R is CₙH₂ₙ₊₁, n≥1; X is at least one of Cl, Br and I; B is at least one of Plumbum (Pb), Germanium (Ge), Bismuth (Bi), Stannum (Sn), Cuprum (Cu), Manganese (Mn) and Stibium (Sb).

10. The manufacturing method of a light-emitting diode (LED) according to claim 9, wherein forming a material having perovskite structure comprises:
preparing a solution of metal halide, the metal halide contains a metallic element which is at least one of Plumbum (Pb), Germanium (Ge), Bismuth (Bi), Stannum (Sn), Cuprum (Cu), Manganese (Mn) and Stibium (Sb);
coating the solution of metal halide onto a substrate and annealing the substrate having been coated with the solution of metal halide, so as to obtain a thin film of metal halide;
immersing the substrate having been formed with the thin film of metal halide into a solution of cesium halide or halogenated alkylamine to obtain the material having perovskite structure.

11. The manufacturing method of a light-emitting diode (LED) according to claim 10, wherein the solution of metal halide has a concentration of 0.1 mol/L-2 mol/L.

12. The manufacturing method of a light-emitting diode (LED) according to claim 10, wherein the solution of metal halide uses at least one of N,N′-dimethylformamide, dimethyl sulfoxide and γ-butyrolactone as a solvent.

13. The manufacturing method of a light-emitting diode (LED) according to claim 10, wherein the solution of cesium halide or halogenated alkylamine uses an alcoholic solution as a solvent.

14. The manufacturing method of a light-emitting diode (LED) according to claim 13, further comprising:
prior to immersing the substrate having been formed with the thin film of metal halide into the solution of cesium halide or halogenated alkylamine, immersing the thin film of metal halide into an alcoholic solution.

15. The manufacturing method of a light-emitting diode (LED) according to claim 9, wherein
forming a material having perovskite structure comprises: forming the material having perovskite structure on the substrate by evaporation process.

16. The manufacturing method of a light-emitting diode (LED) according to claim 15, wherein at least two evaporation sources are provided.

17. The manufacturing method of a light-emitting diode (LED) according to claim 16, wherein the evaporation sources comprise AXₐ and BX_{b}; or the evaporation sources comprise AXₐ, BX′_{b} and BX″_{c},
wherein X′ and X″ are any two of Cl, Br and I.

18. The manufacturing method of a light-emitting diode (LED) according to claim 9, wherein
forming a light-emitting layer comprises at least one of: forming an organic light-emitting layer; and forming a quantum dot light-emitting layer.

19. The manufacturing method of a light-emitting diode (LED) according to claim 9, wherein
forming a functional layer further comprises: forming at least one of an electron injection layer (EIL), a hole injection layer (HIL), an electron barrier layer and a hole barrier layer.

20. A light-emitting device, comprising the light-emitting diode (LED) according to claim 1.
